(19) United States
(12) Patent Application Publication
(10) Pub. No.: US 2022/0385222 A1
(43) Pub. Date: Dec. 1, 2022

(54) VOLTAGE DETECTION AND ADAPTATION METHOD, DEVICE CONTROL METHOD, APPARATUS, AND STORAGE MEDIUM

(71) Applicant: DREAME INNOVATION TECHNOLOGY (SUZHOU) CO., LTD., Suzhou City, Jiangsu Province (CN)

(72) Inventor: HAO YU, Suzhou City, Jiangsu Province (CN)

(21) Appl. No.: 17/776,586

(22) PCT Filed: Dec. 19, 2020
(86) PCT No.: PCT/CN2020/137808

§ 371 Date: May 12, 2022

(30) Foreign Application Priority Data
Dec. 24, 2019 (CN) 201911346238.9
Dec. 24, 2019 (CN) 201911346278.3
Dec. 24, 2019 (CN) 201911347964.2

(51) Int. Cl. H02P 23/14; G01R 19/175

(52) U.S. Cl. CPC H02P 23/14; G01R 19/175

(57) ABSTRACT

A device control method includes: receiving a turn-on signal of a target device, the turn-on signal being adapted to trigger the target device to start working; obtaining a compensation duration, the compensation duration being adapted to offset a delay caused when a voltage zero-crossing detection component detects voltage zero-crossing; and when a zero-crossing signal is received, after the compensation duration, controlling a designated component in the target device to be turned on or off. The zero-crossing signal is a signal sent when the voltage zero-crossing detection component detects that a voltage passes through a zero point. A power supply voltage detection method and a power supply voltage detection apparatus are also disclosed.

### TECHNICAL FIELD

The present application relates to a voltage detection and adaptation method, a device control method, an apparatus, and a storage medium, which belongs to a field of electronic technology.

### BACKGROUND

Electronic devices, such as household appliances, are usually powered using mains voltage. Mains voltage is usually alternating current. Taking the alternating current as a sine wave as an example, if the sine wave is used to control a heating component (such as a heating wire) in a hair dryer to work, the heating component is controlled to be turned on at a position far away from a zero point of the sine wave. This will generate an inrush current to the heating component, and once the inrush current is too large, the heating component will be damaged.

Moreover, in the constant temperature and voltage protection control of the hair dryer, it is necessary to accurately obtain the level of the power supply voltage output by the power supply. Therefore, it is necessary to accurately detect the power supply voltage. In the prior art, the hair dryer has relatively large errors in voltage adaptation and detection.

### SUMMARY

The present application provides a device control method, an apparatus and a storage medium, which can solve the problem that a heating component is easily damaged and the service life of a target device is reduced when a designated component is controlled to be turned on at a position far from a voltage zero-crossing point. The present application provides the following technical solutions:

In a first aspect, a device control method is provided. The method includes:

receiving a turn-on signal of a target device, the turn-on signal being adapted to trigger the target device to start working;

obtaining a compensation duration, the compensation duration being adapted to offset a delay caused when a voltage zero-crossing detection component detects voltage zero-crossing; and

when a zero-crossing signal is received, after the compensation duration, controlling a designated component in the target device to be turned on or off; wherein the zero-crossing signal is a signal sent when the voltage zero-crossing detection component detects that a voltage passes through a zero point.

Alternatively, obtaining the compensation duration includes:

when the voltage zero-crossing detection component detects that the voltage passes through the zero point, obtaining a time duration between a time corresponding to a rising edge of the zero-crossing signal and an actual voltage passing through the zero point, thereby obtaining the compensation duration.

Alternatively, obtaining the compensation duration includes:

obtaining a duty cycle of a power supply of the target device, the power supply being alternating current;

when the voltage zero-crossing detection component detects that the voltage passes through the zero point, obtaining a time duration between a falling edge of the zero-crossing signal and an actual voltage passing through the zero point, thereby obtaining a delay time duration; and

determining the compensation duration based on the duty cycle and the delay time duration.

Alternatively, determining the compensation duration based on the duty cycle and the delay time duration, includes:

determining a difference between a half of the duty cycle and the delay time duration as the compensation duration.

Alternatively, determining the compensation duration based on the duty cycle and the delay time duration, includes:

determining a difference between the duty cycle and the delay time duration as the compensation duration.

Alternatively, the designated component includes a heating component.

Alternatively, when the zero-crossing signal is received, after the compensation duration, controlling the designated component in the target device to be turned on or off, including:

triggering a timer to be turned on when the zero-crossing signal is received, a timing duration of the timer being the compensation duration; and

when a duration of the timer reaches the timing duration, controlling the designated component in the target device to be turned on or off.

In a second aspect, a device control device is provided. The device includes:

a signal receiving module, adapted to receive a turn-on signal of a target device, the turn-on signal being adapted to trigger the target device to start working;

a duration obtaining module, adapted to obtain a compensation duration, the compensation duration being adapted to offset a delay caused when a voltage zero-crossing detection component detects voltage zero-crossing; and

a component control module, adapted to control a designated component in the target device to be turned on or off after the compensation duration when the zero-crossing signal is received, the zero-crossing signal being a signal sent when the voltage zero-crossing detection component detects that a voltage passes through a zero point.

In a third aspect, a device control device is provided. The device control apparatus includes a processor and a memory. A program is stored in the memory, and the program is loaded and executed by the processor to implement the device control method described in the first aspect.

In a fourth aspect, a computer-readable storage medium is provided. A program is stored in the storage medium, and the program is loaded and executed by the processor to implement the device control method described in the first aspect.

The beneficial effects of the present application are: by receiving the turn-on signal of the target device; obtaining the compensation duration; and controlling the designated component in the target device to be turned on or off after the compensation duration when the zero-crossing signal is received, the zero-crossing signal being a signal sent when the voltage zero-crossing detection component detects that the voltage passes through the zero point; it can solve the problem of easily damaging the heating component and reducing the service life of the target device when the heating component is turned on at a position far from the voltage zero-crossing point. Since there is a delay in the detection of the voltage zero-crossing detection component, by determining the compensation duration based on the delay, and combining the zero-crossing signal and the compensation duration, the designated component can be accurately controlled to be turned on or off at the actual voltage zero-crossing point, which can ensure that no inrush current is generated to damage the designated component. At the same time, the precision of controlling the designated component can be improved, and the service life of the designated component can be extended.

In addition, when the designated component is controlled to be turned on at a position far from the voltage zero-crossing point, the current passing through the designated component will undergo a sudden change, and the current sudden change will affect the power supply voltage, thereby causing interference to other devices powered by the power supply voltage. In the present application, by controlling the designated component to be turned on or off at the actual zero-crossing point, it can also avoid the problem that the designated component generates a sudden current that affects the power supply voltage, thereby reducing the interference (that is, conducted interference) of other equipment when the designated component is turned on and off.

The present application provides a power supply voltage detection method, an apparatus and a storage medium, which can solve the problem that when the motor is running, the switch tube in the driving circuit is periodically turned on and off, which will periodically pull down the power supply voltage of the power supply, resulting in the problem that the detected power supply voltage is not accurate. The present application provides the following technical solutions:

In a first aspect, a power supply voltage detection method is provided. The method includes:

obtaining a duty cycle of a motor;

determining a voltage detection moment based on a difference between a working voltage of a power supply and a target voltage at each working moment in the duty cycle, the target voltage being a power supply voltage when the power supply is used to power the motor and when the motor is not turned on; and

determining the power supply voltage of the power supply when a voltage value of the power supply is detected at the voltage detection moment.

Alternatively, determining the voltage detection moment based on the difference between the working voltage of the power supply and the target voltage at each working moment in the duty cycle, includes:

determining a first working moment at which the working voltage is the same as the target voltage in the duty cycle, and determining the first working moment as the voltage detection moment.

Alternatively, the voltage value detected at the voltage detection moment is the power supply voltage of the power supply.

Alternatively, a control signal of the motor is a square wave signal; determining a working moment at which the working voltage is the same as the target voltage in the duty cycle, includes:

determining a starting moment of the duty cycle as the working moment; or

determining an ending moment of the duty cycle as the working moment.

Alternatively, determining the voltage detection moment based on the difference between the working voltage of the power supply and the target voltage at each working moment in the duty cycle, includes:

obtaining the working voltage at each working moment in the duty cycle;

performing curve fitting on variations of the working voltage to obtain a working voltage curve; and

determining a second working moment corresponding to a difference between a maximum voltage value and a preset value in the working voltage curve as the voltage detection moment.

Alternatively, determining the power supply voltage of the power supply when the voltage value of the power supply is detected at the voltage detection moment, includes:

detecting the voltage value of the power supply at the voltage detection moment; and

determining a sum of the voltage value and the preset value as the power supply voltage of the power supply.

Alternatively, obtaining the duty cycle of the motor, includes:

obtaining a control signal of the motor, and determining a cycle of the control signal as the duty cycle;

or,

obtaining an on-off cycle of a switch tube in a driving circuit for controlling the motor, and determining the on-off cycle as the duty cycle.

In a second aspect, a power supply voltage detection apparatus is provided. The device includes:

a cycle obtaining module, adapted to obtain a duty cycle of a motor;

a time determination module, adapted to determine a voltage detection moment based on a difference between a working voltage of a power supply and a target voltage at each working moment in the duty cycle, the target voltage being a power supply voltage when the power supply is used to power the motor and when the motor is not turned on; and

a voltage detection module, adapted to detect a voltage value of the power supply at the voltage detection moment so as to determine the power supply voltage of the power supply.

In a third aspect, a power supply voltage detection apparatus is provided. The device includes a processor and a memory. A program is stored in the memory, and the program is loaded and executed by the processor to implement the power supply voltage detection method described in the first aspect.

In a fourth aspect, a computer-readable storage medium is provided. A program is stored in the storage medium, and the program is loaded and executed by the processor to implement the power supply voltage detection method described in the first aspect.

The beneficial effects of the present application are: by obtaining the duty cycle of the motor; determining the voltage detection moment based on the difference between the working voltage of the power supply and the target voltage at each working moment in the duty cycle; detecting the voltage value of the power supply at the voltage detection moment to determine the power supply voltage of the power supply; it can solve the problem that when the motor is running, the switch tube in the driving circuit is periodically turned on and off, which will periodically pull down the power supply voltage of the power supply, resulting in the problem leading to inaccuracy of detected supply voltage. Because the processing component can control the voltage detection component to collect the working voltage of the power supply at a specified time, and combined with the difference between the working voltage corresponding to the specified time and the target voltage, the working voltage that meets the target voltage can be determined, and the voltage detection accuracy can be improved.

An object of the present invention is to provide a voltage adaptation method, an apparatus and a storage medium, which can solve the problem of excessive power variation caused by a designated component under different power supply voltages.

To achieve the above object, the present invention provides the following technical solutions:

In a first aspect, a voltage adaptation method is provided. The method includes the following steps:

determining a voltage difference between a power supply voltage at a current moment and a power supply voltage at a previous moment; and

determining an opening sequence of a designated component based on the power supply voltage at the current moment, when the voltage difference is greater than a preset threshold value; the opening sequence referring to a period of time that the designated component remains being turned-on during each duty cycle.

Alternatively, determining the opening sequence of the designated component based on the power supply voltage at the current moment, includes:

determining a working power at the current moment based on the power supply voltage at the current moment; and

determining the opening sequence of the designated component according to the working power at the current moment.

Alternatively, determining the opening sequence of the designated component based on the power supply voltage at the current moment, includes:

obtaining a mapping relationship between the power supply voltage and the opening sequence; and

determining the opening sequence of the designated component based on the mapping relationship and the power supply voltage at the current moment.

Alternatively, the method further includes:

controlling the designated component to work according to the opening sequence so as to adjust a power of the designated component.

Alternatively, the method further includes:

obtaining a sampling duration, the sampling duration being an interval between the previous moment and the current moment; and

sampling the power supply voltage when the sampling duration is greater than or equal to a preset duration.

Alternatively, the method further includes:

obtaining the power supply voltage at each moment, and processing the power supply voltage at each moment; and

saving the power supply voltage at each moment after processing.

Alternatively, processing the power supply voltage at the current moment, includes: processing of filtering the power supply voltage at each moment and processing of a mean algorithm.

In a second aspect, a voltage adaptation apparatus is provided. The device includes:

a voltage difference determination module, adapted to determine a voltage difference between a power supply voltage at a current moment and a power supply voltage at a previous moment; and

an opening sequence determination module, adapted to determine an opening sequence of a designated component based on a power supply voltage at the current moment when the voltage difference is greater than a preset threshold; the opening sequence referring to a period of time that the designated component remains being turned-on during each duty cycle.

In a third aspect, a voltage adaptation apparatus is provided. The device includes a processor and a memory. A program is stored in the memory, and the program is loaded and executed by the processor to implement the voltage adaptation method as described above.

In a fourth aspect, a computer-readable storage medium is provided. A program is stored in the storage medium, and the program is loaded and executed by the processor to implement the voltage adaptation method as described above.

The beneficial effects of the present invention are: by determining the voltage difference between the power supply voltage at the current moment and the power supply voltage at the previous moment; when the voltage difference is greater than a preset threshold, the opening sequence of the designated component being determined based on the power supply voltage at the current moment, the opening sequence being the period of time that a designated component remains being turned-on during each duty cycle, thereby preventing the designated component from causing excessive power variation in environments with different supply voltages.

The above description is only an overview of the technical solutions of the present application. In order to understand the technical means of the present application more clearly and implement them in accordance with the contents of the description, the preferred embodiments of the present application and the accompanying drawings are described in detail below.

### BRIEF DESCRIPTION OF DRAWINGS

FIG. 1 is a schematic structural diagram of a device control system provided by an embodiment of the present application;

FIG. 2 is a flowchart of a device control method provided by an embodiment of the present application;

FIG. 3 is a schematic diagram of determining a voltage zero-crossing point provided by an embodiment of the present application;

FIG. 4 is a block diagram of a device control apparatus provided by an embodiment of the present application;

FIG. 5 is a block diagram of a device control apparatus provided by an embodiment of the present application;

FIG. 6 is a schematic structural diagram of a power supply voltage detection system provided by an embodiment of the present application;

FIG. 7 is a schematic diagram of a variation curve of the working voltage of the power supply during the operation of the motor provided by an embodiment of the present application;

FIG. 8 is a flowchart of a power supply voltage detection method provided by an embodiment of the present application;

FIG. 9 is a block diagram of a power supply voltage detection apparatus provided by an embodiment of the present application;

FIG. 10 is a block diagram of a power supply voltage detection apparatus provided by an embodiment of the present application;

FIG. 11 is a flowchart of a voltage adaptation method provided by an embodiment of the present invention;

FIG. 12 is a specific flowchart of a voltage adaptation method provided by an embodiment of the present invention;

FIG. 13 is a block diagram of a voltage adaptation apparatus provided by an embodiment of the present invention; and

FIG. 14 is a voltage adaptation apparatus provided by an embodiment of the present invention.

### DETAILED DESCRIPTION

Specific implementations of the present application will be described in further detail below with reference to the accompanying drawings and embodiments. The following examples are used to illustrate the present application, but are not intended to limit the scope of the present application.

Firstly, some terms involved in the present application are introduced:

Negative Temperature Coefficient (NTC) temperature sensors generally refer to semiconductor materials or components with a large negative temperature coefficient. The operating principle is that the resistance value drops rapidly as the temperature rises.

External interrupt is an internal mechanism for the microcontroller to process external events in real time. When a certain external event occurs, the interrupt system of the microcontroller will force a CPU to suspend the program being executed, and turn to the processing of the interrupt event. After the interrupt is processed, it returns to the interrupted program and continues to execute.

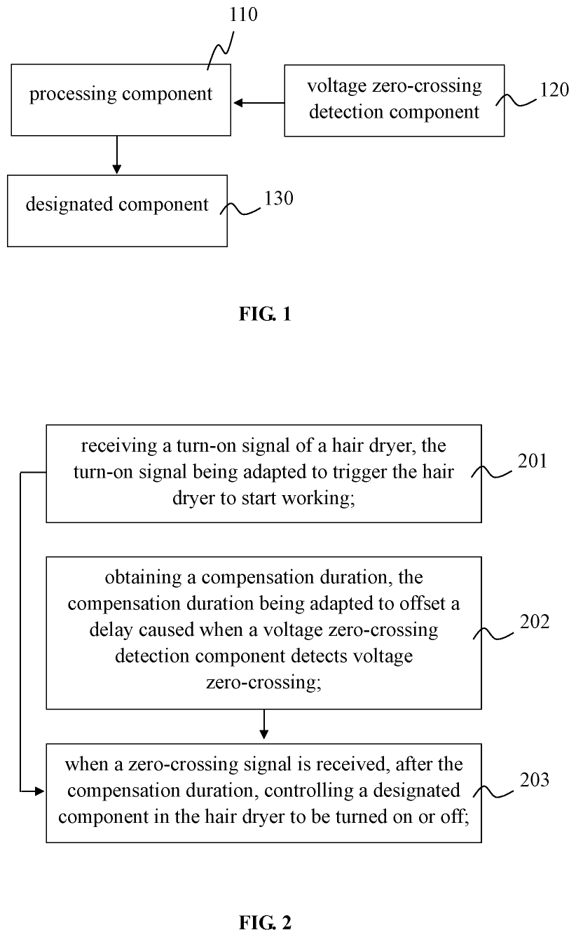

FIG. 1 is a schematic structural diagram of a device control system provided by an embodiment of the present application. As shown in FIG. 1, the system at least includes: a processing component 110, a voltage zero-crossing detection component 120 and a designated component 130.

Alternatively, the device control system can be applied to a hair dryer. Of course, it can also be applied to other devices having the processing component 110, the voltage zero-crossing detection component 120 and the designated component 130. This embodiment does not limit the application scenarios of the device control system.

Both the voltage zero-crossing detection component 120 and the designated component 130 are connected in communication with the processing component 110.

The voltage zero-crossing detection component 120 is used to detect voltage zero-crossing of the power supply which supplies power to a target device. The voltage zero-crossing detection component 120 may be implemented as separate hardware from the processing component 110. Alternatively, the voltage zero-crossing detection component 120 may be software integrated in the processing component 110 or in other hardware devices. Alternatively, the voltage zero-crossing detection component 120 may be a combination of software and hardware. This embodiment does not limit the implementation of the voltage zero-crossing detection component 120.

In an exemplified embodiment, the voltage zero-crossing detection component 120 may be an optocoupler detection component, a transformer detection component, or the like. This embodiment does not limit the implementation of the voltage zero-crossing detection component 120.

Alternatively, the designated component 130 refers to a component installed in the target device and operating directly using alternating current. For example, the designated component 130 is a heating component in the target device, such as a heating wire.

The processing component 110 is adapted to: receive a turn-on signal of the target device, the turn-on signal being adapted to trigger the target device to start working; obtain a compensation duration; and when a zero-crossing signal is received, after the compensation duration, control a designated component in the target device to be turned on or off; wherein the zero-crossing signal is a signal sent when the voltage zero-crossing detection component detects that a voltage passes through a zero point.

Wherein, the compensation duration is adapted to offset a delay caused when the voltage zero-crossing detection component detects voltage zero-crossing.

In this embodiment, the processing component 110 controls the designated component to be turned on or off at the zero-crossing point of the voltage of the power supply, so as to avoid the problem that the designated component is damaged due to inrush current. In addition, since the voltage zero-crossing detection component 120 detects that there is a delay, by determining the compensation duration based on the delay, and combining the position of the voltage zero-crossing point and the compensation duration to more accurately control the startup or shutdown of the designated component, the accuracy of controlling the designated component can be improved, and the service life of the designated component is prolonged.

Alternatively, the device control system may further include other components, such as a power supply, an NTC temperature sensor, a control circuit, and the like, which are not listed one by one in this embodiment.

FIG. 2 is a flowchart of a device control method provided by an embodiment of the present application. This embodiment is described by taking the method applied to the device control system shown in FIG. 1, and the execution subject of each step is the processing component 110 in the system as an example. The method includes at least the following steps:

step 201: receiving a turn-on signal of the target device, and the turn-on signal being used to trigger the target device to start working.

A switch control is provided on the target device. When receiving a control operation acting on the switch control, the processing component receives a turn-on signal from the target device.

step 202: obtaining a compensation duration, the compensation duration being used to offset the delay caused when a voltage zero-crossing detection component detects voltage zero-crossing.

In this embodiment, the compensation duration is determined based on the delay time duration of the voltage zero-crossing detection component detecting the voltage zero-crossing point, so as to offset the influence of the delay time duration to ensure that the processing component controls the designated component to start at the actual voltage zero-crossing point.

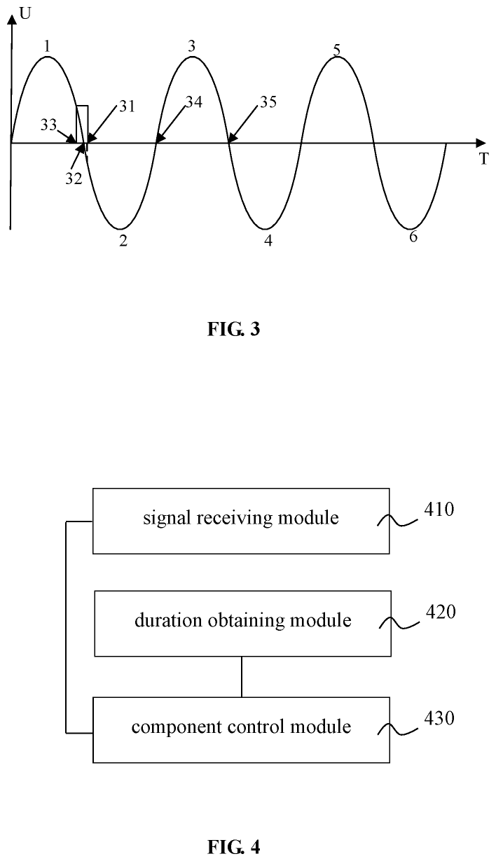

For example, take a waveform of the power supply as a sine wave as an example. Assume that the processing component controls the activation of the designated component at the voltage zero-crossing of the sine wave. The voltage zero-crossing detection component triggers an external interrupt after detecting the voltage zero-crossing. The interrupt signal (the zero-crossing signal) is a pulse waveform. Referring to FIG. 3, if the processing component determines the time 31 corresponding to the falling edge of the zero-crossing signal as the voltage zero-crossing point, the processing component controls the designated component to turn on or off with a delay. The delay time duration is the time between the actual voltage zero-crossing point 32 and the time 31 corresponding to the falling edge. In this embodiment, the influence of the delay time duration can be eliminated by compensating the duration, so that the processing component turns on or off the designated component at the actual voltage zero-crossing point 32.

In an example, obtaining the compensation duration includes: when the voltage zero-crossing detection component detects that the voltage passes through the zero point, obtaining the duration between the time corresponding to the rising edge of the zero-crossing signal and the actual voltage passing through the zero point, thereby obtaining the compensation duration.

Referring to FIG. 3, since the time corresponding to the rising edge 33 of the zero-crossing signal is before the actual voltage zero-crossing, the designated component can be turned on or off by the compensation duration after the time corresponding to the rising edge 33 of the zero-crossing signal. This can control the designated component to be turned on or off at the actual voltage zero-crossing point, thereby improving the control accuracy of the designated component.

Alternatively, the compensation durations corresponding to the same type of voltage zero-crossing detection components are the same. The compensation duration corresponding to each type of voltage zero-crossing detection component is pre-stored in the target device. The processing component determines the corresponding compensation duration according to the type of the current voltage zero-crossing detection component.

In another example, obtaining the compensation duration includes: obtaining a duty cycle of a power supply of the target device, the power supply being alternating current; when the voltage zero-crossing detection component detects that the voltage passes through the zero point, obtaining a time duration between a falling edge of the zero-crossing signal and an actual voltage passing through the zero point, thereby obtaining a delay time duration; and determining the compensation duration based on the duty cycle and the delay time duration.

Alternatively, the delay time durations corresponding to the same type of voltage zero-crossing detection components are the same. The delay time duration corresponding to each type of voltage zero-crossing detection component is pre-stored in the target device. The processing component determines the corresponding delay time duration according to the type of the current voltage zero-crossing detection component.

Wherein the power supply is alternating current.

Alternatively, determining the compensation duration based on the duty cycle and the delay time duration, includes: determining a difference between a half of the duty cycle and the delay time duration as the compensation duration. For example: in FIG. 3, when the voltage zero-crossing detection component detects that the voltage passes through the zero point, the external interrupt of the processing component is triggered (the processing component receives the zero-crossing signal). The processing component turns the designated component on or off when the duration following the falling edge of the zero-crossing signal reaches the difference between half the duty cycle and the delay time duration (position 34). At this time, the compensation duration of the processing component after the falling edge is the actual voltage zero-crossing point 34, which can eliminate the influence of the delay time duration.

Alternatively, the processing component determines the difference between the duty cycle and the delay time duration as the compensation duration. For example: in FIG. 3, the voltage zero-crossing detection component triggers the external interrupt of the processing component when it detects that the voltage passes through the zero point (the processing component receives the zero-crossing signal), and the duration after the falling edge of the zero-crossing signal reaches the duty cycle and the delay time duration. When the duration after the falling edge of the zero-crossing signal reaches the difference between the duty cycle and the delay time duration (position 35), the processing component turns the designated component on or off. At this time, the compensation duration of the processing component after the falling edge is the actual voltage zero-crossing point 35, which can eliminate the influence of the delay time duration.

In another example, the processing component can read the compensation duration from a storage medium. That is, the compensation duration is pre-stored in the target device.

Alternatively, step 202 may be performed after step 201; or may be performed before step 201; or may be performed simultaneously with step 201. This embodiment does not limit the execution order between steps 201 and 202.

step 203: when the zero-crossing signal is received, the designated component in the target device is controlled to be turned on or off after the compensation duration.

Wherein the zero-crossing signal is a signal sent when the voltage zero-crossing detection component detects that the voltage passes through the zero point.

When the zero-crossing signal is received, the timer is triggered to start, and the timing duration of the timer is the compensation duration. When the duration of the timer reaches the timing duration, the designated component in the target device is controlled to be turned on or off.

Alternatively, the designated component is a heating component. The target device stores a control method for the processing component to control the heating component to be turned on and off. For example, in the sine wave shown in FIG. 3, the half-wave control heaters numbered 1, 2, and 3 are turned on; the half-wave control heaters numbered 4 and 5 are turned off (in actual implementation, other control methods may be used, which are not limited in this embodiment). According to this control method, the processing component controls the heating component to be turned on or off after the compensation duration arrives.

In summary, by receiving the turn-on signal of the target device; obtaining the compensation duration; and controlling the designated component in the target device to be turned on or off after the compensation duration when the zero-crossing signal is received, the zero-crossing signal being a signal sent when the voltage zero-crossing detection component detects that the voltage passes through the zero point; the device control method provided by the present embodiment can solve the problem of easily damaging the heating component and reducing the service life of the target device when the heating component is turned on at a position far from the voltage zero-crossing point. Since there is a delay in the detection of the voltage zero-crossing detection component, by determining the compensation duration based on the delay, and combining the zero-crossing signal and the compensation duration, the designated component can be accurately controlled to be turned on or off at the actual voltage zero-crossing point, which can ensure that no inrush current is generated to damage the designated component. At the same time, the precision of controlling the designated component can be improved, and the service life of the designated component can be extended.

In addition, when the designated component is turned on at a position far from the voltage zero-crossing point, the current passing through the designated component will undergo a sudden change. This sudden change in current can affect the power supply voltage, causing interference to other equipment powered by that supply voltage. In the present application, by controlling the designated component to be turned on or off at the actual zero-crossing point, it can also avoid the problem that the designated component produces a sudden current that affects the power supply voltage, thereby reducing the interference (that is, conduction interference) of the designated component on other equipment when it is turned on and off.

FIG. 4 is a block diagram of a device control apparatus provided by an embodiment of the present application. This embodiment is described by taking the device applied to the processing component 110 in the device control system shown in FIG. 1 as an example. The apparatus at least includes the following modules: a signal receiving module 410, a duration obtaining module 420 and a component control module 430.

The signal receiving module 410 is adapted to receive a turn-on signal of the target device. The start signal is used to trigger the target device to start working.

The duration obtaining module 420 is used to obtain the compensation duration. The compensation duration is used to offset the delay caused when the voltage zero-crossing detection component detects voltage zero-crossing.

The component control module 430 is adapted to control the designated component in the target device to be turned on or off after the compensation duration when the zero-crossing signal is received. The zero-crossing signal is a signal sent when the voltage zero-crossing detection component detects that the voltage passes through the zero point.

For relevant details, refer to the above method embodiments.

It should be noted that: when the device control apparatus provided in the above embodiments performs device control, only the division of the above functional modules is used as an example for illustration. In practical applications, the above-mentioned functions can be allocated to different function modules according to requirements. That is, the internal structure of the device control device is divided into different functional modules to complete all or part of the functions described above. In addition, the device control apparatus and the device control method embodiments provided by the above embodiments belong to the same concept, and the specific implementation process thereof is detailed in the method embodiments, which will not be repeated here.

FIG. 5 is a block diagram of a device control apparatus provided by an embodiment of the present application. The apparatus includes at least a processor 501 and a memory 502.

The processor 501 may include one or more processing cores, such as a 4-core processor, an 8-core processor, and the like. The processor 501 may be implemented in at least one hardware form among DSP (Digital Signal Processing), FPGA (Field-Programmable Gate Array), and PLA (Programmable Logic Array). The processor 501 may also include a main processor and a co-processor. The main processor is a processor for processing data in a wake-up state, and is also called a CPU (Central Processing Unit). The co-processor is a low-power processor for processing data in a standby state.

The memory 502 may include one or more computer-readable storage medium. The computer-readable storage medium may be non-transitory. The memory 502 may also include a high-speed random access memory, as well as a non-volatile memory, such as one or more disk storage devices and flash storage devices. In some embodiments, a non-transitory computer-readable storage medium in memory 502 is used to store at least one instruction. The at least one instruction is used to be executed by the processor 501 to implement the device control method provided by the method embodiments in the present application.

In some embodiments, the device control apparatus may optionally further include: a peripheral device port and at least one peripheral device. The processor 501, the memory 502 and the peripheral device port can be connected through a BUS or a signal line. Each peripheral device can be connected to the peripheral device port through the BUS, the signal line or a circuit board. Illustratively, the peripheral device includes, but is not limited to, audio circuits, power supplies, and the like.

Of course, the device control apparatus may further include fewer or more components, which is not limited in this embodiment.

Alternatively, the present application further provides a computer-readable storage medium. A program is stored in the computer-readable storage medium. The program is loaded and executed by the processor to implement the device control method of the above method embodiment.

Alternatively, the present application also provides a computer product. The computer product includes a computer-readable storage medium. A program is stored in the computer-readable storage medium. The program is loaded and executed by the processor to implement the device control method of the above method embodiment.

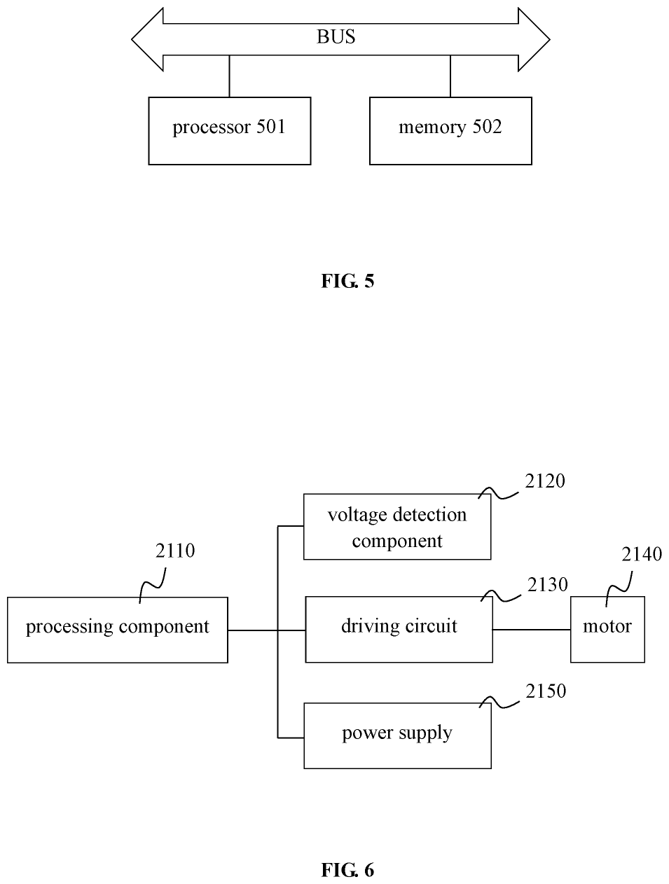

FIG. 6 is a schematic structural diagram of a power supply voltage detection system provided by an embodiment of the present application. As shown in FIG. 6, the system at least includes: a processing component 2110, a voltage detection component 2120 and a driving circuit 2130 connected in communication with the processing component 2110, a motor 2140 connected in communication with the driving circuit 2130, and a power supply 2150 connected in communication with the processing component 2110.

Alternatively, the power supply voltage detection system can be applied to a hair dryer. Of course, it can also be applied to other devices that need to perform power supply voltage detection, and this embodiment does not limit the application scenarios of the power supply voltage detection system.

Alternatively, the power supply 2150 is direct current obtained by rectifying alternating current through a rectifier circuit. The power supply 2150 is used to provide DC voltage for the motor 2140.

The voltage detection component 2120 is installed at an output end of the power supply 2150. The voltage detection component 2120 is used to detect the power supply voltage of the power supply 2150 and send the detected supply voltage to the processing component 2110.

The processing component 2110 is adapted to determine the voltage detection moment of the voltage detection component 2120, and control the voltage detection component 2120 to detect the power supply voltage of the power supply 2150 at the voltage detection moment.

The processing component 2110 is also used to control the driving circuit 2130 to drive the motor 2140 to operate. Alternatively, the driving circuit 2130 controls the operation of the motor by outputting a control signal to the motor. The control signal may be a square wave signal. The square wave signal includes a sine wave, a rectangular wave, etc., and the type of the square wave signal is not limited in this embodiment.

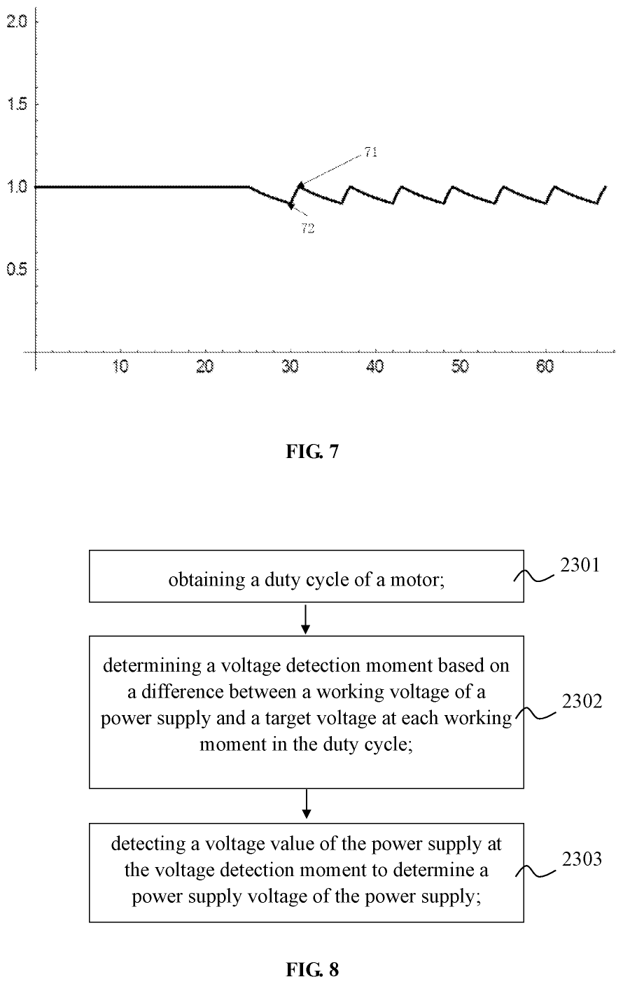

When the motor is running, a switch tube in the driving circuit 2130 is periodically turned on and off. At this time, the power supply voltage (or bus voltage) of the power supply 2150 is periodically pulled down, for example, referring to the variation curve of the working voltage of the power supply during the operation of the motor shown in FIG. 7. Based on this technical problem, the processing component 2110 is used to obtain the duty cycle of the motor 2140. The voltage detection moment is determined based on the difference between the working voltage of the power supply 2150 and the target voltage at each working moment in the duty cycle. The voltage value of the power supply 2150 is detected at the time of voltage detection to determine the power supply voltage of the power supply 2150. The target voltage is the power supply voltage when the motor is not turned on when the power supply is used to power the motor. In this way, the processing component 2110 can control the voltage detection component 2120 to collect the working voltage of the power supply 2150 at a specified time, and combine the voltage difference corresponding to the specified time to determine the working voltage that meets the target voltage, thereby improving the voltage detection accuracy.

FIG. 8 is a flowchart of a power supply voltage detection method provided by an embodiment of the present application. This embodiment is described by taking the method applied to the power supply voltage detection system shown in FIG. 6 as an example, and the execution subject of each step is the processing component 2110 in the system. The method includes at least the following steps:

step 2301: obtaining the duty cycle of the motor;

wherein the way of obtaining the duty cycle of the motor includes but is not limited to: obtaining the control signal of the motor, and determining a cycle of the control signal as the duty cycle; or, obtaining an on-off cycle of the switch tube in the driving circuit of the control motor, and determining the on-off cycle as the duty cycle.

Taking the working voltage curve shown in FIG. 7 as an example, in one duty cycle of the motor, the working voltage firstly drops and then rises. At this time, the curve corresponding to the falling stage is the curve corresponding to the turn-on process of the switch tube; and the curve corresponding to the rising stage is the curve corresponding to the turn-off process of the switch tube.

step 2302: determining the voltage detection moment based on the difference between the working voltage of the power supply and the target voltage at each working moment in the duty cycle.

The target voltage is the power supply voltage when the power supply is used to power the motor and when the motor is not turned on.

Alternatively, based on the difference between the working voltage of the power supply and the target voltage at each working moment in the duty cycle, the methods for determining the voltage detection moment include but are not limited to the following:

A first method: determining a first working moment in the duty cycle when the working voltage is the same as the target voltage, and determining the first working moment as the voltage detection moment.

In an example, the control signal of the motor is a square wave signal, and determining the working moment in the duty cycle when the working voltage is the same as the target voltage includes: determining a starting moment of the duty cycle as the working moment; or, determining an ending time of the duty cycle as the working moment.

For example, for the working voltage curve shown in FIG. 7, the time 71 at the end of the duty cycle is determined as the working moment. At this time, the working voltage corresponding to the working moment is the same as the power supply voltage when the motor is not working.

A second method: obtaining the working voltage at each working moment in the duty cycle; performing curve fitting on variations of the working voltage to obtain a working voltage curve; and determining a second working moment corresponding to a difference between a maximum voltage value and a preset value in the working voltage curve as the voltage detection moment.

Assuming that the variation of the working voltage is shown in FIG. 7, and the preset value is the difference between the maximum voltage and the minimum voltage, the second working moment is the time 72 corresponding to the minimum working voltage.

step 2303: detecting the voltage value of the power supply at the voltage detection moment to determine the power supply voltage of the power supply.

For the determination of the voltage detection moment in the first method, the voltage value detected at the voltage detection moment is the power supply voltage of the power supply.

For the determination of the voltage detection moment in the second method, the voltage value of the power supply is detected at the voltage detection moment; and the sum of the voltage value and the preset value is determined as the power supply voltage of the power supply.

For example: when the preset value is the difference between the maximum voltage and the minimum voltage on the working voltage curve, and the voltage detection moment is the working moment corresponding to the voltage minimum value, then the power supply voltage is the working voltage detected at the voltage detection moment plus a preset value, and the obtained value is the same as the power supply voltage.

In summary, by obtaining the duty cycle of the motor; determining the voltage detection moment based on the difference between the working voltage of the power supply and the target voltage at each working moment in the duty cycle; detecting the voltage value of the power supply at the voltage detection moment to determine the power supply voltage of the power supply; the power supply voltage detection method provided in this embodiment can solve the problem that when the motor is running, the switch tube in the driving circuit is periodically turned on and off, which will periodically pull down the power supply voltage of the power supply, resulting in the problem leading to inaccuracy of detected supply voltage. Because the processing component can control the voltage detection component to collect the working voltage of the power supply at a specified time, and combined with the difference between the working voltage corresponding to the specified time and the target voltage, the working voltage that meets the target voltage can be determined, and the voltage detection accuracy can be improved.

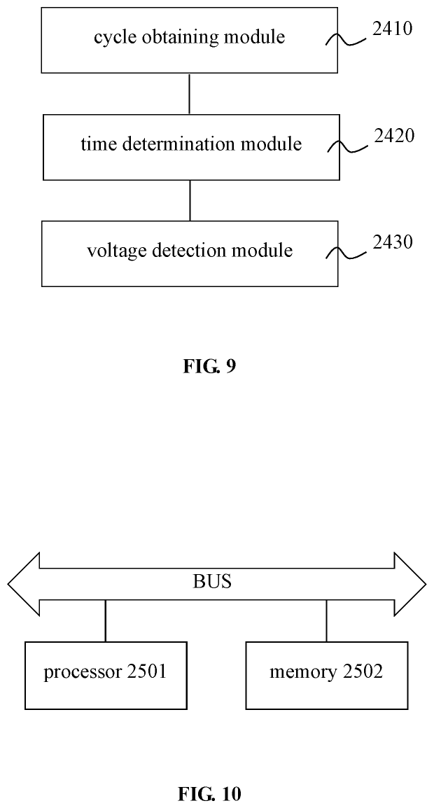

FIG. 9 is a block diagram of a power supply voltage detection apparatus provided by an embodiment of the present application. This embodiment is described by taking the apparatus being applied to the processing component 2110 in the power supply voltage detection system shown in FIG. 6 as an example. The apparatus includes at least the following modules: a cycle obtaining module 2410, a time determination module 2420 and a voltage detection module 2430.

The cycle obtaining module 2410 is used to obtain the duty cycle of the motor.

The time determination module 2420 is adapted to determine the voltage detection moment based on the difference between the working voltage of the power supply and the target voltage at each working moment in the duty cycle. The target voltage is the power supply voltage when the power supply is used to power the motor and when the motor is not turned on.

The voltage detection module 2430 is adapted to detect the voltage value of the power supply at the voltage detection moment to determine the power supply voltage of the power supply.

For relevant details, refer to the above method embodiments.

It should be noted that: when the power supply voltage detection apparatus provided in the above embodiments performs power supply voltage detection, only the division of the above-mentioned functional modules is used as an example for illustration. In practical applications, the above-mentioned functions can be allocated to different function modules according to requirements. That is, the internal structure of the power supply voltage detection apparatus is divided into different functional modules to complete all or part of the functions described above. In addition, the power supply voltage detection apparatus and the power supply voltage detection method embodiments provided by the above embodiments belong to the same concept, and the specific implementation process thereof is detailed in the method embodiments, which will not be repeated here.

FIG. 10 is a block diagram of a power supply voltage detection apparatus provided by an embodiment of the present application. The apparatus includes at least a processor 2501 and a memory 2502.

The processor 2501 may include one or more processing cores, such as a 4-core processor, an 8-core processor, and the like. The processor 2501 may be implemented in at least one hardware form among DSP (Digital Signal Processing), FPGA (Field-Programmable Gate Array), and PLA (Programmable Logic Array). The processor 2501 may also include a main processor and a co-processor. The main processor is a processor for processing data in a wake-up state, and is also called a CPU (Central Processing Unit). The co-processor is a low-power processor for processing data in a standby state.

The memory 2502 may include one or more computer-readable storage medium. The computer-readable storage medium may be non-transitory. The memory 2502 may also include a high-speed random access memory, as well as a non-volatile memory, such as one or more disk storage devices and flash storage devices. In some embodiments, a non-transitory computer-readable storage medium in memory 2502 is used to store at least one instruction. The at least one instruction is used to be executed by the processor 2501 to implement the power supply voltage detection method provided by the method embodiments in the present application.

In some embodiments, the power supply voltage detection apparatus may optionally further include: a peripheral device port and at least one peripheral device. The processor 2501, the memory 2502 and the peripheral device port can be connected through a BUS or a signal line. Each peripheral device can be connected to the peripheral device port through the BUS, the signal line or a circuit board. Illustratively, the peripheral device includes, but is not limited to, audio circuits, power supplies, and the like.

Of course, the power supply voltage detection apparatus may further include fewer or more components, which is not limited in this embodiment.

Alternatively, the present application further provides a computer-readable storage medium. A program is stored in the computer-readable storage medium. The program is loaded and executed by the processor to implement the power supply voltage detection method of the above method embodiment.

Alternatively, the present application also provides a computer product. The computer product includes a computer-readable storage medium. A program is stored in the computer-readable storage medium. The program is loaded and executed by the processor to implement the power supply voltage detection method of the above method embodiment.

An analog-to-digital converter (ADC) refers to an electronic component that converts an analog signal into a digital signal.

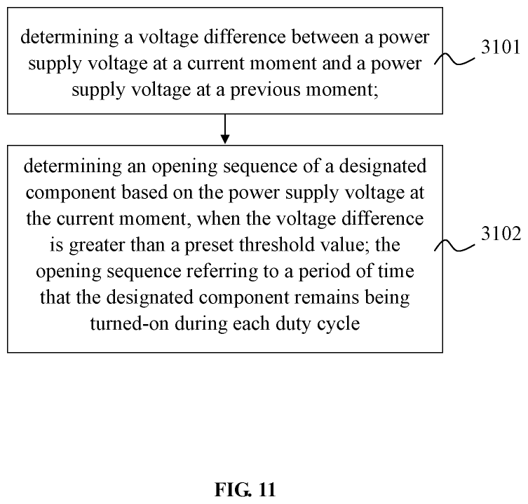

FIG. 11 is a flowchart of a voltage adaptation method provided by an embodiment of the present invention. The voltage adaptation method of the present invention is suitable for devices such as a hair dryer, and the application of the voltage adaptation method is not specifically limited in the present invention. Correspondingly, the designated component in this embodiment is a heating component. Of course, in other embodiments, the designated component may also be other components, which is not specifically limited here, and depends on the actual situation. The method includes at least the following steps:

step 3101: determining a voltage difference between a power supply voltage at a current moment and a power supply voltage at a previous moment;

The power supply voltage at each moment is obtained, and the power supply voltage at each moment is sampled by an analog-to-digital converter. The power supply voltage at each moment is processed, and the processed power supply voltage at each moment is saved. Alternatively, the processing of the power supply voltage at each moment includes: the processing of filtering the power supply voltage at each moment and the processing of the mean algorithm. The mean algorithm may include a K-means clustering algorithm, a natural mean algorithm, and the like. By filtering the power supply voltage at each moment and processing the mean algorithm, the external interference on the obtained power supply voltage at each moment is eliminated. It is true that in other embodiments, other processing may also be performed on the power supply voltage at each moment, which is not specifically limited here, and depends on the actual situation, as long as the corresponding effect is achieved.

The voltage difference is determined by processing and saving the power supply voltage at each moment. The process of determining the voltage difference is as follows: obtaining the power supply voltage at the current moment, and subtracting the power supply voltage at the current moment and the power supply voltage at the previous moment to obtain the voltage difference between the two. Wherein, if the current moment is the first sampling moment, the power supply voltage at the previous moment is zero.

step 3102: determining an opening sequence of a designated component based on the power supply voltage at the current moment, when the voltage difference is greater than a preset threshold value; the opening sequence referring to a period of time that the designated component remains being turned-on during each duty cycle.

The opening sequence of the designated component at the current moment can be determined by the relationship between the voltage and the power, which specifically includes: determining the working power at the current moment based on the power supply voltage at the current moment; determining the opening sequence of the designated component according to the working power at the current moment, the control opening of the power closest to the power supply voltage setting power is matched by the array comparison.

Of course, in other embodiments, the opening sequence of the designated component at the current moment can also be determined by the relationship between the voltage and the opening sequence, which specifically includes: obtaining a mapping relationship between the power supply voltage and the opening sequence; and determining the opening sequence based on the mapping relationship and the power supply voltage at the current moment. The mapping relationship between the power supply voltage and the opening sequence is a one-to-one mapping relationship, and then the designated component is controlled to work according to the opening sequence to adjust the power of the designated component.

Alternatively, the method further includes: obtaining a sampling duration. The sampling duration is an interval between the previous moment and the current moment. When the sampling duration is greater than or equal to the preset duration, the power supply voltage is sampled. When the time interval from the previous moment exceeds the sampling time, the power supply voltage is sampled again to prevent the power supply voltage from changing greatly when the device is working, which will cause damage to the specified components, and even more serious problems will cause hidden dangers in use.

When the voltage difference is less than or equal to the preset threshold, the sampling duration is directly obtained to sample the power supply voltage at the next moment.

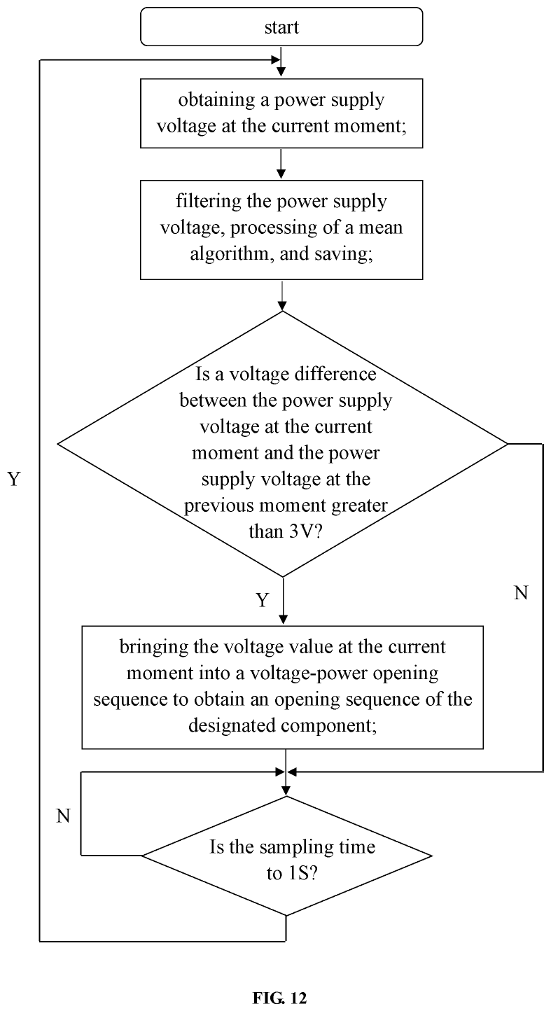

Referring to FIG. 12, the voltage distribution method of the present invention will be described below with a specific embodiment. In this embodiment, the preset threshold is 3V, and the sampling duration is 1 s. The power supply voltage at the current moment is sampled through an analog-to-digital converter. Then, filtering and averaging algorithm processing are performed on the power supply voltage at the current moment, and the processed power supply voltage at the current moment is saved. The voltage difference between the power supply voltage at the current moment and the power supply voltage at the previous moment is calculated. When the voltage difference is greater than 3V, the power supply voltage at the current moment is brought into the voltage-power relationship diagram to determine the working power at the current moment. The opening sequence of the designated component according to the working power at the current moment is determined. If the voltage difference is not greater than 3V, the sampling duration is obtained. When the sampling duration is greater than or equal to 1 s, the power supply voltage at the next moment is sampled. If the sampling duration is less than 1 s, the power supply voltage at the next moment will not be sampled until the sampling duration is greater than or equal to 1 s.

In summary, by determining the voltage difference between the power supply voltage at the current moment and the power supply voltage at the previous moment; when the voltage difference is greater than a preset threshold, the opening sequence of the designated component is determined based on the power supply voltage at the current moment. The opening sequence is the period of time that the designated component remains being turned-on during each duty cycle, thereby preventing the designated component from causing excessive power variation in environments with different supply voltages.

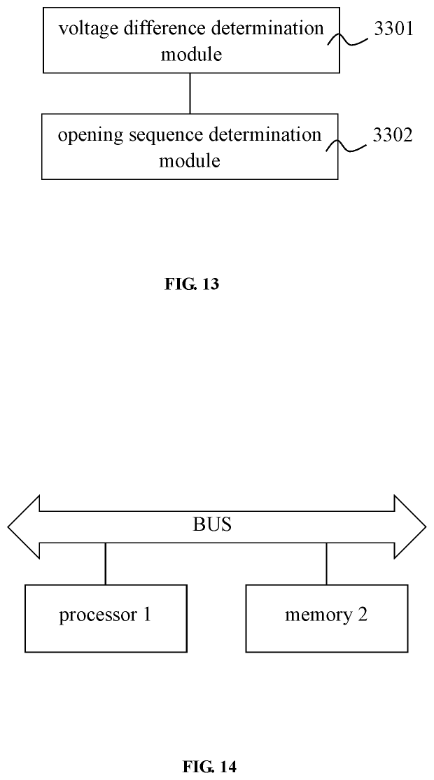

FIG. 13 is a block diagram of a voltage adaptation apparatus provided by an embodiment of the present invention. The apparatus at least includes:

a voltage difference determination module 3301, adapted to determine the voltage difference between the power supply voltage at the current moment and the power supply voltage at the previous moment;

an opening sequence determination module 3302, adapted to determine the opening sequence of the designated component based on the power supply voltage at the current moment when the voltage difference is greater than a preset threshold. The opening sequence refers to the period of time that the designated component remains being turned-on during each duty cycle.

For relevant details, refer to the above method embodiments.

It should be noted that: when the voltage adaptation apparatus provided in the above embodiments performs voltage adaptation, only the division of the above functional modules is used as an example for illustration. In practical applications, the above-mentioned functions can be allocated to different function modules according to requirements. That is, the internal structure of the voltage adaptation apparatus is divided into different functional modules to complete all or part of the functions described above. In addition, the voltage adaptation apparatus and the voltage adaptation method embodiments provided by the above embodiments belong to the same concept, and the specific implementation process thereof is detailed in the method embodiments, which will not be repeated here.

FIG. 14 is a voltage adaptation apparatus provided by an embodiment of the present invention. The apparatus at least includes a processor 1 and a memory 2.

The processor 1 may include one or more processing cores, such as a 4-core processor 1, an 8-core processor 1, and the like. The processor 1 may be implemented by at least one hardware form among DSP (Digital Signal Processing), FPGA (Field-Programmable Gate Array), and PLA (Programmable Logic Array). The processor 1 may also include a main processor and a co-processor. The main processor is a processor for processing data in a wake-up state, and is also called a CPU (Central Processing Unit, central processing unit). The co-processor is a low-power processor for processing data in a standby state.

The memory 2 may include one or more computer-readable storage medium. The computer-readable storage medium may be non-transitory. The memory 2 may also include a high-speed random access memory 2, and a non-volatile memory 2, such as one or more magnetic disk storage devices and flash storage devices. In some embodiments, a non-transitory computer-readable storage medium in memory 2 is used to store at least one instruction. The at least one instruction is used to be executed by the processor 1 to implement the voltage adaptation method provided by the method embodiment of the present invention.

In some embodiments, the voltage adaptation apparatus may optionally further include: a peripheral device port and at least one peripheral device. The processor 1, the memory 2 and the peripheral device port can be connected through a BUS or a signal line. Each peripheral device can be connected to the peripheral device port through the BUS, the signal line or a circuit board. Illustratively, the peripheral device includes, but is not limited to, radio frequency circuits, touch display screens, audio circuits, and power supplies.

Of course, the voltage adaptation apparatus may further include fewer or more components, which is not limited in this embodiment.

Alternatively, the present application provides a computer-readable storage medium. A program is stored in the computer-readable storage medium. The program is used to implement the voltage adaptation method as described above when executed by the processor.

Alternatively, the present application also provides a computer product. The computer product includes a computer-readable storage medium. A program is stored in the computer-readable storage medium. The program is loaded and executed by the processor to implement the voltage adaptation method of the above method embodiment.

The technical features of the above-described embodiments can be combined arbitrarily. In order to simplify the description, all possible combinations of the technical features in the above embodiments are not described. However, as long as there is no contradiction in the combination of these technical features, they should be considered to be within the scope of the description in this specification.

The above-mentioned embodiments only represent several embodiments of the present application, and the descriptions thereof are relatively specific and detailed, but should not be construed as a limitation on the scope of the present invention. It should be noted that, for those skilled in the art, without departing from the concept of the present application, several modifications and improvements can be made, which all belong to the protection scope of the present application. Therefore, the scope of protection of the patent of the present application shall be subject to the appended claims.

1. A device control method, comprising:
receiving a turn-on signal of a target device, the turn-on signal being adapted to trigger the target device to start working;
obtaining a compensation duration, the compensation duration being adapted to offset a delay caused when a voltage zero-crossing detection component detects voltage zero-crossing; and
when a zero-crossing signal is received, after the compensation duration, controlling a designated component in the target device to be turned on or off; wherein the zero-crossing signal is a signal sent when the voltage zero-crossing detection component detects that a voltage passes through a zero point.

2. The method according to claim 1, wherein obtaining the compensation duration comprises:
when the voltage zero-crossing detection component detects that the voltage passes through the zero point, obtaining a time duration between a time corresponding to a rising edge of the zero-crossing signal and an actual voltage passing through the zero point, thereby obtaining the compensation duration.

3. The method according to claim 1, wherein obtaining the compensation duration comprises:
obtaining a duty cycle of a power supply of the target device, the power supply being alternating current;
when the voltage zero-crossing detection component detects that the voltage passes through the zero point, obtaining a time duration between a falling edge of the zero-crossing signal and an actual voltage passing through the zero point, thereby obtaining a delay time duration; and
determining the compensation duration based on the duty cycle and the delay time duration.

4. The method according to claim 3, wherein determining the compensation duration based on the duty cycle and the delay time duration, comprises:
determining a difference between a half of the duty cycle and the delay time duration as the compensation duration.

5. The method according to claim 3, wherein determining the compensation duration based on the duty cycle and the delay time duration, comprises:
determining a difference between the duty cycle and the delay time duration as the compensation duration.

6. The method according to claim 1, wherein the designated component comprises a heating component.

7. The method according to claim 1, wherein when the zero-crossing signal is received, after the compensation duration, controlling the designated component in the target device to be turned on or off, comprising:
triggering a timer to be turned on when the zero-crossing signal is received, a timing duration of the timer being the compensation duration; and
when a duration of the timer reaches the timing duration, controlling the designated component in the target device to be turned on or off.

8-10. (canceled)

11. A power supply voltage detection method, comprising:
obtaining a duty cycle of a motor;
determining a voltage detection moment based on a difference between a working voltage of a power supply and a target voltage at each working moment in the duty cycle, the target voltage being a power supply voltage when the power supply is used to power the motor and when the motor is not turned on; and
determining the power supply voltage of the power supply when a voltage value of the power supply is detected at the voltage detection moment.

12. The method according to claim 11, wherein determining the voltage detection moment based on the difference between the working voltage of the power supply and the target voltage at each working moment in the duty cycle, comprises:
determining a first working moment at which the working voltage is the same as the target voltage in the duty cycle, and determining the first working moment as the voltage detection moment.

13. The method according to claim 12, wherein the voltage value detected at the voltage detection moment is the power supply voltage of the power supply.

14. The method according to claim 12, wherein a control signal of the motor is a square wave signal; determining a working moment at which the working voltage is the same as the target voltage in the duty cycle, comprises:
determining a starting moment of the duty cycle as the working moment; or
determining an ending moment of the duty cycle as the working moment.

15. The method according to claim 11, wherein determining the voltage detection moment based on the difference between the working voltage of the power supply and the target voltage at each working moment in the duty cycle, comprises:
obtaining the working voltage at each working moment in the duty cycle;
performing curve fitting on variations of the working voltage to obtain a working voltage curve; and
determining a second working moment corresponding to a difference between a maximum voltage value and a preset value in the working voltage curve as the voltage detection moment.

16. The method according to claim 15, wherein determining the power supply voltage of the power supply when the voltage value of the power supply is detected at the voltage detection moment, comprises:
detecting the voltage value of the power supply at the voltage detection moment; and
determining a sum of the voltage value and the preset value as the power supply voltage of the power supply.

17. The method according to claim 11, wherein obtaining the duty cycle of the motor, comprises:
obtaining a control signal of the motor, and determining a cycle of the control signal as the duty cycle;
or,
obtaining an on-off cycle of a switch tube in a driving circuit for controlling the motor, and determining the on-off cycle as the duty cycle.

18. A power supply voltage detection apparatus, comprising:
a cycle obtaining module, adapted to obtain a duty cycle of a motor;
a time determination module, adapted to determine a voltage detection moment based on a difference between a working voltage of a power supply and a target voltage at each working moment in the duty cycle, the target voltage being a power supply voltage when the power supply is used to power the motor and when the motor is not turned on; and
a voltage detection module, adapted to detect a voltage value of the power supply at the voltage detection moment so as to determine the power supply voltage of the power supply.

19. The power supply voltage detection apparatus according to claim 18, further comprising a processor and a memory;
wherein a program is stored in the memory; and the program is loaded and executed by the processor to implement a power supply voltage detection method.

20. The power supply voltage detection apparatus according to claim 18, wherein a program is stored in a storage medium, and the program is adapted to implement a power supply voltage detection method.

21-30. (canceled)
